(19) United States
(12) Patent Application Publication
(10) Pub. No.: US 2026/0366142 A1
(43) Pub. Date: Nov. 19, 2026

(54) A ROBUST ICEFILL METHOD TO PROVIDE VOID FREE TRENCH FILL FOR LOGIC AND MEMORY APPLICATIONS

(71) Applicant: Lam Research Corporation, Fremont, CA (US)

(72) Inventors: Pulkit Agarwal, Beaverton, OR (US); Jonathan Grant Baker, King City, OR (US); Mamoru Imade, Sherwood, OR (US); Shiva Sharan Bhandari, Sherwood, OR (US); Jennifer Leigh Petraglia, Lake Oswego, OR (US)

(21) Appl. No.: 19/128,007

(22) PCT Filed: Nov. 7, 2023
(86) PCT No.: PCT/US2023/078999

§ 371 Date: May 7, 2025

Related U.S. Application Data
(60) Provisional application No. 63/382,880, filed on Nov. 8, 2022.
(60) Provisional application No. 63/383,679, filed on Nov. 14, 2022.

(51) Int. Cl. C23C 16/04; C23C 16/455; C23C 16/505; C23C 16/56; H01J 37/32; H10P 14/60; H10P 14/692

(52) U.S. Cl. CPC C23C 16/045; C23C 16/45536; C23C 16/45544; C23C 16/505; C23C 16/56; H01J 37/32449; H10P 14/6336; H10P 14/6339; H10P 14/69215; H01J 2237/332

(57) ABSTRACT

Methods of filling a gap with a dielectric material including using an inhibition plasma during deposition. The inhibition plasma increases a nucleation barrier of the deposited film. The inhibition plasma selectively interacts near the top of the feature, inhibiting deposition at the top of the feature compared to the bottom of the feature, enhancing bottom-up fill.

### INCORPORATION BY REFERENCE

An Application Data Sheet is filed concurrently with this specification as part of the present application. Each application that the present application claims benefit of or priority to, as identified in the concurrently filed Application Data Sheet, is incorporated by reference herein in their entireties and for all purposes.

### BACKGROUND

Many semiconductor device fabrication processes involve formation of films including silicon-containing films such as silicon oxide or silicon nitride. Plasma enhanced atomic layer deposition (PEALD) may be used to deposit silicon-containing films. Depositing a high-quality film can be particularly challenging when depositing films in gaps. Challenges can include the formation of voids and/or seams in the films.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Disclosed herein are methods and systems of filling gaps in structures. In one aspect of the embodiments herein, a method is provided for filling gaps, the method including: providing a substrate in a process chamber, the substrate having one or more structures, each structure including a gap; and performing a first set of cycles of: (a) exposing the substrate to an inhibition plasma to inhibit deposition on a first portion of each gap, and (b) after (a), depositing a dielectric material in each gap, wherein, during a first subset and a second subset of the first set of cycles exposing the substrate to the inhibition plasma occurs for a first duration and during the second subset of the first set of cycles at least one non-duration based parameter of exposing the substrate to the inhibition plasma is modified.

In some embodiments, the non-duration based parameter is a flow rate of inhibition species, flow rate of a dilution gas, pressure, or a radio frequency (RF) power. In some embodiments, the first subset of the first set of cycles inhibits deposition in the gaps to a greater depth of the gaps than the second subset of the first set of cycles. In some embodiments, exposing the substrate to an inhibition plasma includes flowing an inhibition species into the process chamber, and wherein a flow of inhibition species is lower during the second subset of the first set of cycles than the first subset of the first set of cycles. In some embodiments, a difference in the flow of inhibition species between the first subset of the first set of cycles and the second subset of the first set of cycles is between about 1 sccm and about 5 sccm. In some embodiments, exposing the substrate to an inhibition plasma includes co-flowing an inhibition species with an inert gas into the process chamber, and wherein a ratio of inhibition species to inert gas is higher during the second subset of the first set of cycles than the first subset of the first set of cycles. In some embodiments, the inhibition species includes a nitrogen-containing species. In some embodiments, exposing the substrate to an inhibition plasma includes providing radio frequency (RF) energy to the process chamber, and wherein a RF is lower during the second subset of the first set of cycles than the first subset of the first set of cycles. In some embodiments, a difference in RF power between the first subset of the first set of cycles and the second subset of the first set of cycles is between about 50 W and about 700 W. In some embodiments, the RF power is between about 250 W and about 1250 W per substrate. In some embodiments, each of the one or more structures has one or more reentrancy features. In some embodiments, at least one of the reentrancy features has a variation in critical dimension of at least 10% within the substrate. In some embodiments, the at least one non-duration based parameter is modified based on the variation in critical dimension of the at least one reentrancy feature of the one or more structures. In some embodiments, at least one of the reentrancy features has a variation in depth of at least 10% between structures. In some embodiments, the at least one non-duration based parameter is modified based on the variation in depth of the at least one reentrancy feature of the one or more structures. In some embodiments, the dielectric material is an oxide material. In some embodiments, the oxide material is silicon dioxide. In some embodiments, further including performing a second set of cycles of: exposing the substrate to an inhibition plasma to inhibit deposition on a second portion of the gaps, wherein, during a first subset and a second subset of the second set of cycles exposing the substrate to an inhibition plasma occurs for a second duration different than the first duration and during the second subset of the second set of cycles the at least one non-duration based parameter of the inhibition plasma is modified; and after (a), depositing a dielectric material in the gaps.

In another aspect of the embodiments herein, a system of filling a gap is provided, the system including: a process chamber, and one or more memories and one or more processors, the one or more memories being configured with computer-executable instructions for controlling the one or more processors for: providing a substrate in the process chamber, the substrate having one or more structures, each structure including a gap; and performing a first set of cycles of: (a) exposing the substrate to an inhibition plasma to inhibit deposition on a first portion of each gap, and (b) after (a), depositing a dielectric material in each gap, wherein, during a first subset and a second subset of the first set of cycles exposing the substrate to the inhibition plasma occurs for a first duration and during the second subset of the first set of cycles at least one non-duration based parameter of exposing the substrate to the inhibition plasma is modified.

Disclosed herein are methods and systems of filling gaps in structures at stations of a tool that has different fill rates between stations. In another aspect of the embodiments herein, a system is provided, the system including: a process chamber including a plurality of stations; one or more processors and one or more memories configured for: receiving a plurality of substrates each having a structure with a gap in the plurality of stations, performing a first set of cycles in each of the stations of: (a) exposing a substrate to an inhibition plasma to inhibit deposition on a first portion of the gaps, and (b) after (a), depositing a dielectric material in the gaps, and after performing the first set of cycles, performing a second set of cycles in each station of a first subset of the plurality of stations of: (c) depositing dielectric material in only the gaps of substrates in stations of the first subset of the plurality of stations.

In some embodiments, after the first set of cycles a first substrate in a station of the first subset of the plurality of stations has a lower depth of fill of dielectric material than a second substrate of the plurality of substrates. In some embodiments, the second substrate is in a station that is not part of the first subset of the plurality of stations. In some embodiments, after the second set of cycles the first substrate has a depth of fill of dielectric material that is substantially the same as the second substrate. In some embodiments, the one or more processors and one or more memories are further configured for, prior to (c), exposing a substrate to an inhibition plasma to inhibit deposition on a first portion of the gaps. In some embodiments, the one or more processors and one or more memories are further configured for not performing (c) in one or more stations that are not in the first subset of the plurality of stations. In some embodiments, the one or more processors and one or more memories are further configured for flowing one or more reactants to each of the one or more stations during the second set of cycles. In some embodiments, during the second set of cycles, the one or more reactants do not react with the substrates in stations that are not in the first subset of the plurality of stations. In some embodiments, the one or more processors and one or more memories are further configured for providing radio-frequency (RF) power to the first subset of the plurality of stations during the second set of cycles and not providing RF power to stations that are not in the first subset of the plurality of stations during the second set of cycles. In some embodiments, the one or more processors and one or more memories are further configured for flowing one or more reactants to each of the plurality of stations during the second set of cycles. In some embodiments, the one or more processors and one or more memories are further configured for flowing one or more reactants to the first subset of the plurality of stations during the second set of cycles and not flowing the one or more reactants to stations that are not in the first subset of the plurality of stations during the second set of cycles. In some embodiments, further including a second process chamber, and wherein the first subset of the plurality of stations are part of the process chamber and the stations that are not in the first subset of the plurality of stations are part of the second process chamber.

In another aspect of the embodiments herein, a method is provided, the method including: receiving a plurality of substrates each having a structure with a gap in the plurality of stations, performing a first set of cycles in each of the stations of: (a) exposing a substrate to an inhibition plasma to inhibit deposition on a first portion of the gaps, and (b) after (a), depositing a dielectric material in the gaps, and after performing the first set of cycles, performing a second set of cycles in each station of a first subset of the plurality of stations of: (c) depositing dielectric material in only the gaps of substrates in stations of the first subset of the plurality of stations.

In some embodiments, after the first set of cycles a first substrate in a station of the first subset of the plurality of stations has a lower depth of fill of dielectric material than a second substrate of the plurality of substrates. In some embodiments, the second substrate is in a station that is not part of the first subset of the plurality of stations. In some embodiments, after the second set of cycles the first substrate has a depth of fill of dielectric material that is substantially the same as the second substrate. In some embodiments, further including, prior to (c), exposing a substrate to an inhibition plasma to inhibit deposition on a first portion of the gaps. In some embodiments, further including not performing (c) in one or more stations that are not in the first subset of the plurality of stations. In some embodiments, further including flowing one or more reactants to each of the one or more stations during the second set of cycles. In some embodiments, during the second set of cycles, the one or more reactants do not react with the substrates in stations that are not in the first subset of the plurality of stations. In some embodiments, further including providing radio-frequency (RF) power to the first subset of the plurality of stations during the second set of cycles and not providing RF power to stations that are not in the first subset of the plurality of stations during the second set of cycles. In some embodiments, further including flowing one or more reactants to each of the plurality of stations during the second set of cycles. In some embodiments, further including flowing one or more reactants to the first subset of the plurality of stations during the second set of cycles and not flowing the one or more reactants to stations that are not in the first subset of the plurality of stations during the second set of cycles. In some embodiments, further including a second process chamber, and wherein the first subset of the plurality of stations are part of the process chamber and the stations that are not in the first subset of the plurality of stations are part of the second process chamber.

These and other features of the disclosed embodiments will be described in detail below with reference to the associated drawings.

### BRIEF DESCRIPTION OF DRAWINGS

FIG. 1 presents a flow diagram of operations for one example embodiment.

FIGS. 2A-D present illustrations of example embodiments to reduce void formation in features.

FIG. 3 presents a flow diagram of operations for one example embodiment.

FIGS. 4A-B presents an example illustration of gapfill variation between chambers according to various embodiments herein.

FIG. 5 presents a flow diagram of operations for atomic layer deposition processes.

FIG. 6 presents a flow diagram of operations for one example embodiment.

FIGS. 7-10 are schematic diagrams of examples of process chambers for performing methods in accordance with disclosed embodiments.

### DETAILED DESCRIPTION

In the following description, numerous specific details are set forth to provide a thorough understanding of the presented embodiments. The disclosed embodiments may be practiced without some or all these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

Semiconductor fabrication processes often include dielectric gap fill using chemical vapor deposition (CVD) and/or atomic layer deposition (ALD) methods to fill features. Described herein are methods of filling features with dielectric material including but not limited to oxide films and silicon-containing films such as silicon oxide, and related systems and apparatuses. The methods described herein can be used to fill vertically oriented features formed in a substrate. Such features may be referred to as gaps, recessed features, negative features, unfilled features, or simply features. Filling such features may be referred to as gapfill. Features formed in a substrate can be characterized by one or more of narrow and/or re-entrant openings, constrictions within the feature, and high aspect ratios. In some implementations, a feature may have an aspect ratio of at least about 2:1, at least about 4:1, at least about 6:1, at least about 20:1, at least about 100:1, or greater. The substrate may be a silicon wafer, e.g., a 200-mm wafer, a 300-mm wafer, or a 450-mm wafer, including wafers having one or more layers of material such as dielectric, conducting, or semi-conducting material deposited thereon.

One aspect of the disclosure relates to a method of using an inhibition plasma during atomic layer deposition (ALD) of dielectric material in gaps that facilitates void-free bottom gapfill. The inhibition plasma creates a passivated surface and increases a nucleation barrier of the deposited ALD film. When the inhibition plasma interacts with material in the feature, the material at the bottom of the feature receives less plasma treatment than material located closer to a top portion of the feature or in field because of geometrical shadowing effects. As a result, deposition at the top of the feature is selectively inhibited and deposition in lower portions of the feature proceeds with less inhibition or without being inhibited. As a result, bottom-up fill is enabled in an ALD process, which creates a more favorable sloped profile that mitigates seam effect and prevents void formation. Halogen-containing plasmas can be effective inhibition plasmas. For example, for some applications, a plasma generated from nitrogen trifluoride (NF₃) may provide an inhibition effect in a substantially reduced time compared to a plasma generated from molecular nitrogen (N₂).

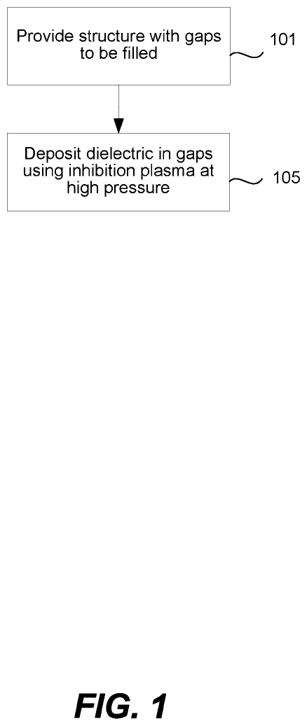

FIG. 1 is a process flow diagram that illustrates a method of filling gaps with dielectric material. The method begins with providing a structure with one or more gaps to be filled. (101). The structure may be formed by one or more layers of material deposited on a substrate. The substrate may be a silicon or other semiconductor wafer, e.g., a 200-mm wafer, a 300-mm wafer, or a 450-mm wafer, including wafers having one or more layers of material, such as dielectric, conducting, or semi-conducting material deposited thereon. The methods may also be applied to for gapfill other substrates, such as glass, plastic, and the like, including in the fabrication of microelectromechanical (MEMS) devices.

Examples of structures include 3D NAND structures, DRAM structures, and shallow trench isolation (STI) structures. The structures include gaps with the sidewalls of the gaps formed by a material susceptible to etch. In one example, 3D NAND structure includes oxide-nitride-oxide-nitride (ONON) stacks covered with a poly Si layer. In another example, structures may include lateral/tunnel structures that extend horizontally from a common vertical trench. Other examples of sidewall materials include oxides, metals, and semiconducting materials. The methods described herein are not limited to a particular class of sidewall material and may be used to inhibit any susceptible material.

Dielectric material is deposited in the gaps using an inhibition plasma. (105). As discussed further below, this can involve cycles of inhibition plasma followed by cycles of ALD of the dielectric material. An inhibition plasma treatment may be characterized by an inhibition effective depth (IED). The IED describes a depth above which deposition will be inhibited. By varying the parameters of the inhibition plasma treatment, including time, pressure, species, and flow rates, the IED may be increased or decreased. The IED may be affected by multiple parameters, including the particular species used, a duration of the inhibition plasma treatment, plasma power, proportion of gas flow that is the inhibiting species (rather than a carrier gas such as an inert gas, e.g., helium or argon), and pressure. In particular, the duration used for inhibition may have a large effect on the IED. For example, plasmas generated from nitrogen trifluoride (NF₃) may inhibit microns deep gaps within seconds, and smaller depths may be inhibited by exposure to an inhibition plasma for as little as 0.1 seconds. For high aspect ratio and deep structures, e.g., at least about 100:1 and 3 μm or greater structures, NF₃ is an ideal choice of species for inhibition to sufficiently inhibit the structure to avoid pinch off, while also not fully inhibiting the structure. Other species may also be used, including halogen-containing species such as NF₃ and non-halogen-containing species, such as N₂.

During design of a bottom-up fill process, multiple inhibition blocks may be planned where an inhibition plasma treatment may be changed between inhibition blocks. For example, an inhibition plasma treatment may be tuned so that the IED is closer to the bottom of the feature, e.g., 75% of the total depth of the feature is inhibited. Cycles of an ALD process may then be performed to fill the bottom 25% of the feature. The inhibition plasma parameters may then be adjusted to inhibit, e.g., the top 50% of the feature (relative to the total depth and notwithstanding any fill), and then the next bottom portion of the feature is filled.

In some embodiments, the IED may be affected by the geometry of the feature to be filled. For example, a reentrancy feature affects the mass transport of inhibition species in a feature. A reentrancy feature may be characterized by a narrowing of the distance between sidewalls at a depth within the gap, where the distance may be measured along an axis parallel to a top or bottom surface of the substrate, and where the sidewall distance is greater above and below the reentrancy feature. Reentrancy features present a challenge during deposition as the narrow portion within the gap increases the risk of a void forming below the smaller gap. A “pinch-off” occurs where deposition fills the gap at the reentrancy feature prior to fully filling below the reentrancy feature, thereby producing an internal void.

One method to reduce pinch-off and internal voids is to inhibit deposition at and above the reentrancy feature until sufficient deposition has occurred below the reentrancy feature. A plasma inhibition treatment may be tuned to inhibit at the reentrancy feature, and inhibition may be performed until the gap has been sufficiently filled. Once the gap has been sufficiently filled deposition may occur at and/or above the reentrancy feature with a reduced risk of producing an internal void. The inhibition plasma may then be adjusted to reduce the IED so that deposition occurs at and/or above the reentrancy feature. Notably, the gap need not be entirely filled below the reentrancy feature prior to deposition at the reentrancy feature, but merely sufficiently filled to reduce the risk of pinch-off and voids. As deposition is inhibited at the reentrancy feature yet not below the reentrancy feature, the gap below the reentrancy feature may sufficiently fill.

While an IED at the depth of a reentrancy feature may reduce or eliminate pinch-off, In some embodiments the reentrancy features and/or the entire gap may have within-wafer (WW) and/or wafer-to-wafer (W2W) variation. In some embodiments, this variation may cause a corresponding WW or W2W variation in the IED. This is undesirable and may increase the risk of a pinch-off when the IED is greater or lesser than the depth of a reentrancy feature for the reasons noted above. In some embodiments, depth of a reentrancy feature may vary by at least about 5%, at least about 10%, at least about 15%, or between about 10% and about 20%. The variation in the IED may result from the effect of a reentrancy feature on the IED. For example, variations in the critical dimension throughout the gap and at the reentrancy feature affects mass transport within the feature, which changes the depth at which the inhibition plasma affects the surface, i.e., the IED. Furthermore, the depth of reentrancy features may vary, such that a single IED does not inhibit at the depth of the reentrancy features for all gaps being filled. This may be undesirable as the gap may be inhibited too far above or below a reentrancy feature, causing a pinch-off at the reentrancy feature and thus a void.

To address this variation, in some embodiments an inhibition plasma treatment may be modified to inhibit within a range at a target depth. For example, multiple inhibition plasma treatments may be tuned to have an IED at 78%, 75%, and 72% depth rather than only 75%. This may be accomplished by performing multiple inhibition plasma treatments. Typically, multiple inhibition plasma treatments are performed for a specific target IED, e.g., 75%, as the inhibition effect may diminish before the gap is sufficiently filled. Once the gap is sufficiently filled the inhibition plasma may be modified to target a different IED, e.g., 50%. However, in some embodiments the inhibition plasma may modified to inhibit across a range including the target IED. In some embodiments ten or more inhibition plasma treatments may be performed having the same parameters to target a single IED, e.g., the same duration, plasma power, gas flow, etc., which may instead be modified to inhibit within a range including the single IED.

Thus, in some embodiments the inhibition plasma treatment may be tuned such that the inhibition plasma treatment inhibits slightly more and/or less than an average depth of a reentrancy feature. This may be useful when the depth of a reentrancy feature varies by at least about 5%, at least about 10%, at least about 15%, or between about 10% and about 20%, or when the critical dimension of a reentrancy feature varies by at least about 5%, at least about 10%, at least about 15%, or between about 10% and about 20%. In some embodiments, a non-duration based parameter may be changed between inhibition plasma treatments. A non-duration based parameter may be any parameter excluding the time allotted for (i.e., the duration of) an operation, e.g., the inhibition plasma treatment. Duration may have the greatest effect on the IED of an inhibition plasma treatment, such that changing the duration may significantly increase or decrease the IED, which is undesirable. A desired change in IED may be less than about 3%, less than about 5%, less than about 10%, or less than about 20%, such that changing the duration may change the IED more than desired. In some embodiments, a least-sensitive parameter of the inhibition plasma treatment may be modified. In some embodiments, a plasma power of the inhibition plasma treatment may be the least-sensitive parameter. For example, a 10% increase in HF power may change the IED by less than 3%, compared to a 10% change in duration that causes a more than 4.5% change in IED.

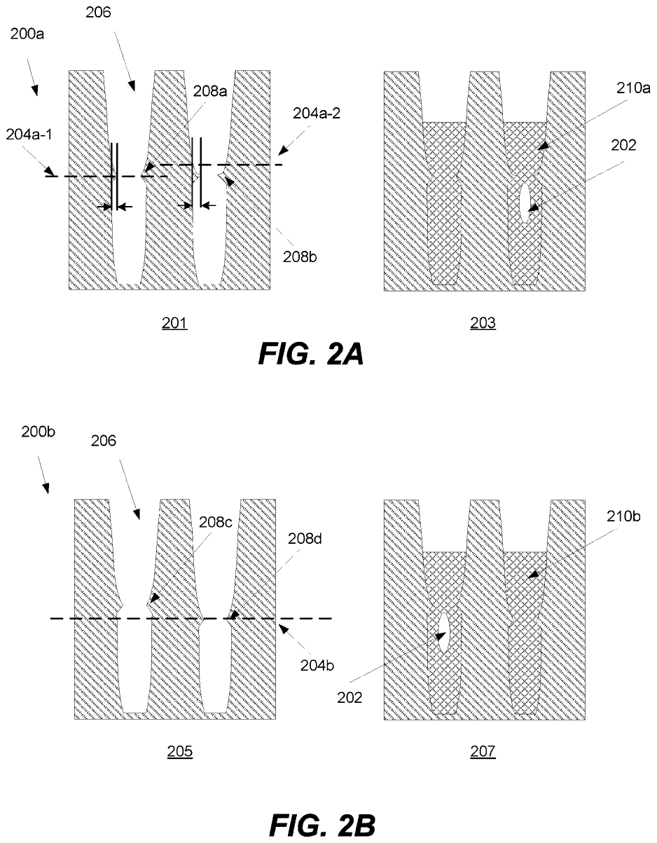

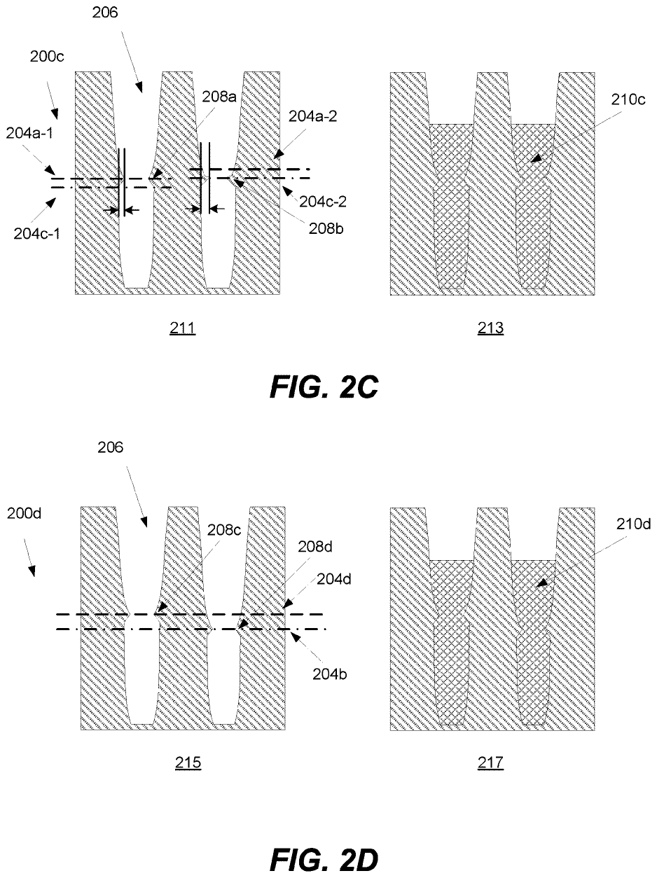

FIGS. 2A-2D illustrate gapfill where gaps have varying reentrancy features. FIGS. 2A-2B present structures illustrating what may occur when variations in reentrancy features are present using inhibition plasma treatment at a single IED. In FIG. 2A an example structure 200a is presented during various stages of a gap fill method described herein. At 201, the structure 200a is shown with gaps 206 to be filled with a dielectric material. In the example of FIG. 2A, the gaps 206 are formed between structures that may include dielectric, conducting, or semi-conducting material. In some embodiments, structure 200 is a low aspect ratio structure. In some embodiments, low aspect ratio structures may be structures having an aspect ratio between about 3:1 and about 7:1. In some embodiments, low aspect ratio structures may have a depth of at least about 1 μm. In some embodiments, structure 200 is a high aspect ratio structure. In some embodiments, a conformal layer is provided (not shown), which may be a liner deposited prior to deposition using an inhibition plasma. The conformal layer may protect the underlying layer from unwanted etch during a subsequent inhibition plasma treatment. In some embodiments, the conformal layer is a silicon nitride layer. In some embodiments, the conformal layer is a silicon oxide layer. In some embodiments, the conformal layer is a metal oxide layer, e.g., titanium oxide, zirconium oxide, tin oxide, hafnium oxide, or combinations thereof. In some embodiments the conformal layer is a silicon layer, e.g., poly Si. In some embodiments a conformal layer is not present.

In FIG. 2A, gaps 206 may be characterized by reentrancy features 208a-b. Reentrancy feature 208a is smaller than reentrancy feature 208b, as indicated by the vertical lines, wherein the size may be based on a difference between the critical dimension at the narrowest and the critical dimension at the widest part of the reentrancy feature.

In some embodiments, the depth of the reentrancy feature, the critical dimension at any point in the gap, and the difference between the critical dimension at the reentrancy feature and the critical dimension above/below the reentrancy feature may vary. Each of these variations may affect the IED and/or mass transport within the feature and thus affect deposition.

At 201 the structure 200a may also be characterized by inhibition effective depth (IED) lines 204a1-2. IED lines 204a1-2 illustrate a depth of inhibition resulting from a plasma inhibition treatment. Notably, IED line 204a-1 at reentrancy feature 208a is below reentrancy feature 208 a, while the IED line 204a-2 at reentrancy feature 208b is above reentrancy feature 208b. This difference in IED may result despite each gap being exposed to the same inhibition plasma. The different in IED results from the difference in size between reentrancy features 208a and 208b. As reentrancy feature 208b is larger than reentrancy features 208a, the mass flow of inhibition species is smaller within the gap having reentrancy feature 208b, causing a corresponding decrease in IED.

At 203, the gaps 206 are filled with dielectric material 210a in a bottom-up manner. At 203 the gap having reentrancy feature 208b has a void 202. This void results from IED line 204a-2 being too shallow, i.e., insufficient inhibition. As the inhibition effect was not deep enough, deposition at the reentrancy feature occurred, causing a pinch-off effect leading to void 202.

Similarly, FIG. 2B illustrates another example of how voids may occur due to variations in reentrancy features. At 205, structure 200b has gaps 206 having reentrancy features 208c and 208d. Reentrancy feature 208d is at a greater depth within the gap than reentrancy feature 208 c. After an inhibition plasma treatment, IED line 204b is the same for both gaps, however it inhibits deeper in the feature (i.e., at a greater depth) than reentrancy feature 208c. At 207, the gaps 206 are filled with dielectric material 210b in a bottom-up manner, such that there is relatively little or no deposition on the sidewalls above the fill line. However, void 202 forms in dielectric material 210b. This void may result from the IED being deeper than reentrancy feature 208c despite the IED being the correct depth for reentrancy feature 208d.

FIGS. 2C-2D present structures illustrating a method of improving uniformity and decreasing voids resulting from variation in reentrancy structures.

FIG. 2C illustrates a structure 200c that has gaps 206 and reentrancy features 208a-b. Structure 200c may be the same structure as structure 200a. At 211, structure 200c has two sets of IED lines. IED lines 204a-1 and 204a-2 may be the same as shown in FIG. 2A. Additionally, IED lines 204c1-2 are shown and may result from a different inhibition plasma treatment. IED lines 204c-1 and 204c-2 have different depths based on the difference between reentrancy features 208a and 208b. IED lines 204c-1 and 204c-2 are slightly deeper in gaps 206. Thus, IED line 204c-1 may be an appropriate depth of inhibition for reentrancy feature 208 a, while IED line 204c-2 may be an appropriate depth of inhibition for reentrancy feature 208b.

In some embodiments, the variation in critical dimension within a gap and the variation in reentrancy feature size may be at least about 5%, at least about 10%, at least about 15%, or between about 10% and about 20%. In some embodiments, a variation in critical dimension or reentrancy feature size may have a larger impact on IED than variation in reentrancy feature depth. For example, a 10% variation in reentrancy feature depth may affect the desired IED by 10%, while a 10% variation in critical dimension or reentrancy feature size may affect the desired IED by more than about 15%. Thus, in various embodiments, parameters for inhibition plasma treatments may be varied to target IED lines 204a-1, 204a-2, 204c-1, and 204c-2 based on the variations in critical dimension, reentrancy feature size, and reentrancy feature depth.

At 213, gaps 206 are filled with dielectric material 210c in a bottom-up manner. In particular, dielectric material 210c does not have voids. This results from filling the gaps using an inhibition plasma treatment that results in IED lines 204c-1 and 204c-2, followed by additional gapfill using an inhibition plasma treatment that results in IED lines 204a-1 and 204a-2. Notably, while IED lines 204a1-2 and IED lines 204c1-2 are both shown at 211, it should be understood that they correspond to different inhibition plasma treatments (consider that the lines show a depth above which sidewalls are inhibited, so IED 204c-1 may already imply inhibition at line 204a-1). Gapfill may be initially performed using an inhibition plasma treatment resulting in IED lines 204c-1 and 204c-2. The inhibition plasma treatment may then be modified to result in IED lines 204a-1 and 204a-2 and gapfill continues until the gaps are filled above reentrancy features 208a and 208b.

FIG. 2D illustrates a structure 200d that has gaps 206 and reentrancy features 208c-d, similar to FIG. 2B. At 215, structure 200d has two sets of IED lines. IED line 204b may be the same as shown in FIG. 2B, while IED line 204d may result from a different inhibition plasma treatment. Notably, while IED line 204b is at the correct depth for reentrancy feature 208d, IED line 204d is at the correct depth for reentrancy feature 208 c.

At 217, gaps 206 are filled with dielectric material 210d in a bottom-up manner. Dielectric material 210d does not have voids. This results from filling the gaps using an inhibition plasma treatment that results in IED line 204b, followed by additional gapfill using an inhibition plasma treatment that results in IED line 204d. Notably, while IED lines 204b and 204d are both shown at 215, it should be understood that they correspond to different inhibition plasma treatments. ). Gapfill may be initially performed using an inhibition plasma treatment resulting in IED line 204b. The inhibition plasma treatment may then be modified to result in IED line 204d and gapfill continues until the gaps are filled above reentrancy features 208c and 208d.

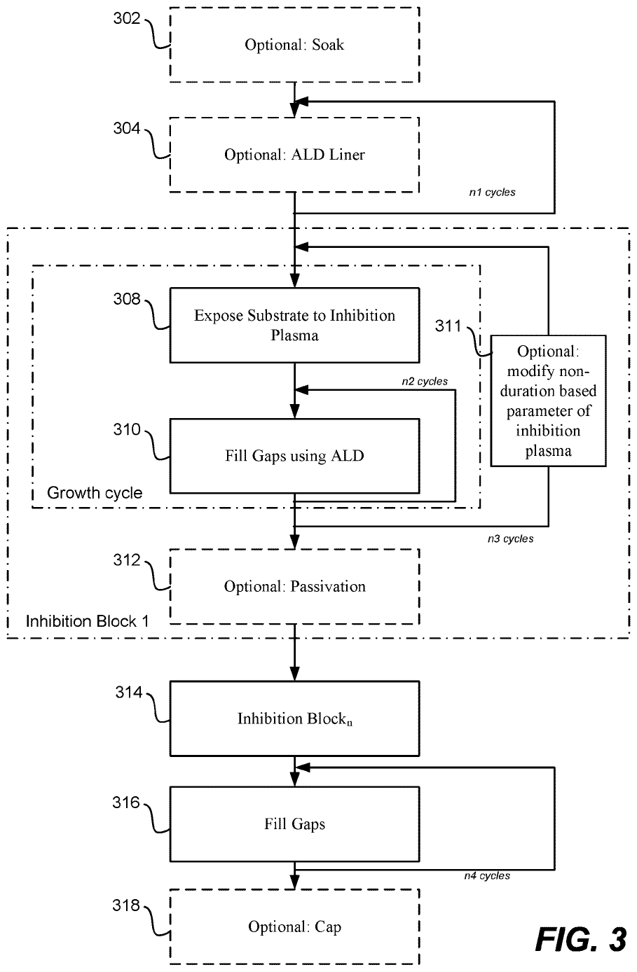

FIG. 3 shows an example of a process sequence that may be used in accordance with the disclosed embodiments. The process sequence in FIG. 3 include treating a substrate with an inhibition plasma. Other operations (e.g., soak, passivation) may be omitted in certain embodiments and operations may be added in certain embodiments. In the example process sequence of FIG. 3, one or more wafers undergo gap fill. The process may begin with a soak after being provided to a deposition chamber. (302). This can be useful, for example, to remove particles or other pretreatment. Then, n1 cycles of ALD deposition of a liner are performed. (304). Further details of a liner ALD are discussed below.

After the optional liner is deposited, n inhibition blocks are performed, with the operations of the first inhibition block (n=1) shown. The first operation is the inhibition plasma, which is a surface treatment. (308) As discussed above, the plasma may include halogen species including anion and radical species such as F⁻, Cl⁻, I⁻, Br⁻, fluorine radicals, etc. Other inhibition plasmas may be used. In some embodiments, the inhibition plasma is generated from non-halogen containing species, including nitrogen-containing species and nitrogen-containing, non-halogen-containing species. For example, plasmas generated from molecular nitrogen (N₂), molecular hydrogen (H₂), ammonia (NH₃), amines, diols, diamines, aminoalcohols, thiols, alkyl halides, halides, HF, fluorine-containing species, chlorine-containing species, iodine-containing species, or combinations thereof may be used as inhibition plasmas. In some embodiments, the inhibition plasma treatment is performed at high pressure as described herein.

When the inhibition plasma interacts with material in the feature, the material at the bottom of the feature receives less plasma treatment than material located closer to a top portion of the feature or in field because of geometrical shadowing effects. As a result, deposition at the top of the feature is selectively inhibited and deposition in lower portions of the feature proceeds with less inhibition or without being inhibited. In FIG. 3, the next operation in the inhibition block is n2 cycles of ALD fill. (310). The dielectric material is deposited selectively at the bottom of the feature. The inhibition plasma and the n2 cycles of ALD fill together make a growth cycle. This can be repeated n3 times to continue filling the feature with intermittent inhibition operations when the inhibition effect diminishes. The number of growth cycles in an inhibition block may depend on the re-entrancy of the feature, i.e., if it narrows at one or more points from the bottom to the top of the feature. Features that exhibit more re-entrancy may use a longer inhibition time or multiple inhibition blocks. In some embodiments, n2 cycles of ALD fill may comprise at least one ALD cycle, at least about 10 ALD cycles, or between 1 and about 15 ALD cycles. The inhibition plasma and the n2 cycles of ALD fill together make a growth cycle. This can be repeated n3 times to continue filling the feature with intermittent inhibition operations when the inhibition effect diminishes.

In some embodiments, a non-duration based parameter of the inhibition plasma may be changed between growth cycles. (311). For example, a plasma power or inhibitor species flow may be changed. In some embodiments, the non-duration based parameter may be changed to decrease the IED of the inhibition plasma treatment. In some embodiments, the duration of an inhibition plasma treatment is the primary parameter that is adjusted to change the IED, as the IED is highly sensitive to the duration of exposure to an inhibition plasma. However, changing duration may change the IED more than the variation in reentrancy features changes the IED, such that a void may still occur due to over- or under-inhibition. By changing a parameter that the IED is less sensitive to, e.g., plasma power, the IED may similarly be slightly decreased to properly inhibit a variation between reentrancy features. In some embodiments, the least sensitive parameter of the inhibition plasma may be changed, wherein the least sensitive parameter may be selected from a group including inhibition species flow rate, dilution gas flow rate (e.g., N₂ or Ar), and plasma power.

Thus, in some embodiments, in a first growth cycle, the inhibition plasma may inhibit to a first IED, and one or more cycles of ALD fill are performed. During a subsequent second growth cycle a non-duration based parameter of the inhibition plasma is modified to decrease the IED (notably, the duration of the inhibition plasma may be the same during the first growth cycle and the second growth cycle). Additional cycles of ALD fill may be performed. This modification may be performed multiple times depending on the variation of reentrancy features, e.g., more modifications to the inhibition plasma within a single inhibition block may be performed for a larger variation in reentrancy figure critical dimensions.

In the example of FIG. 3, the inhibition block ends with an optional passivation operation. (312). This is a surface treatment that removes residual inhibitor and can also densify the deposited film. In some embodiments, an oxygen plasma is used.

One or more additional inhibition blocks, including growth cycle and passivation, may be performed for a total of n inhibition blocks. (314). The number of inhibition blocks depends on how much material is used to fill the feature. Inhibition plasma, ALD, and passivation conditions may be changed from inhibition block to inhibition block to fill the feature. For example, an inhibition plasma duration may be 20 seconds until the bottom quarter of the feature is filled (inhibition block 1), then changed to 5 seconds for the middle 50% of the structure (inhibition block 2), etc. Each inhibition block may have a different IED, where process parameters for an inhibition plasma treatment for an inhibition block are changed to target a different IED. Each inhibition block may fill a portion of the feature below an IED of that inhibition block.

In some embodiments, the change in a non-duration based parameter in (311) may change the IED by less than about 3%, less than about 5%, less than about 10%, or less than about 20%. In some embodiments, the change in a non-duration based parameter in (311) may change the IED by less than about 100 nm, less than about 200 nm, less than about 300 nm, less than about 400 nm, or less than about 700 nm. This may be contrasted to changes in the inhibition plasma between inhibition blocks, where the inhibition plasma may be modified to change the IED by more than about 10% or more than about 20%. For example, in some embodiments a gapfill process may have four inhibition blocks, where parameters for an inhibition plasma between inhibition blocks may be set to inhibit at 8 um, 4 um, 2 um, and 1 um. Changes to the inhibition plasma within an inhibition block may be performed to properly inhibit reentrancy features that vary WW or W2W. In some embodiments, such reentrancy feature variations may cause a change in IED that is much less than the change in IED between inhibition blocks. In some embodiments the change in a target IED between inhibition blocks is maximized to efficiently fill a feature without voids. As the IED is highly sensitive to a duration of the inhibition plasma treatment, duration is typically modified between inhibition blocks. By contrast, the change to an inhibition plasma within an inhibition block may be much smaller, such that duration is too sensitive to be changed to target variations in reentrancy features. As noted above, a small change in inhibition plasma treatment duration may have a significantly larger effect on IED than a similarly small change in RF power or inhibition species flow.

In various embodiments, parameters other than duration may be changed between inhibition plasma treatments to target a range of IED as discussed above. Decreasing the flow of inhibition species (as a proportion of total flow), decreasing RF power, and/or decreasing pressure may decrease the IED. In some embodiments, the flow of inhibition species may change by between about 1 sccm and about 5 sccm between a first inhibition plasma treatment and a second inhibition plasma treatment. In some embodiments, the RF power may change by between about 50 W and about 700 W between a first inhibition plasma treatment and a second inhibition plasma treatment.

When the feature is nearly filled, inhibition may no longer be necessary, and the fill can be completed with n4 cycles of ALD fill. (316). In some embodiments, an optional cap or overburden layer of dielectric may then be deposited. (318). Plasma enhanced chemical vapor deposition (PECVD) may be used at this stage for a fast deposition.

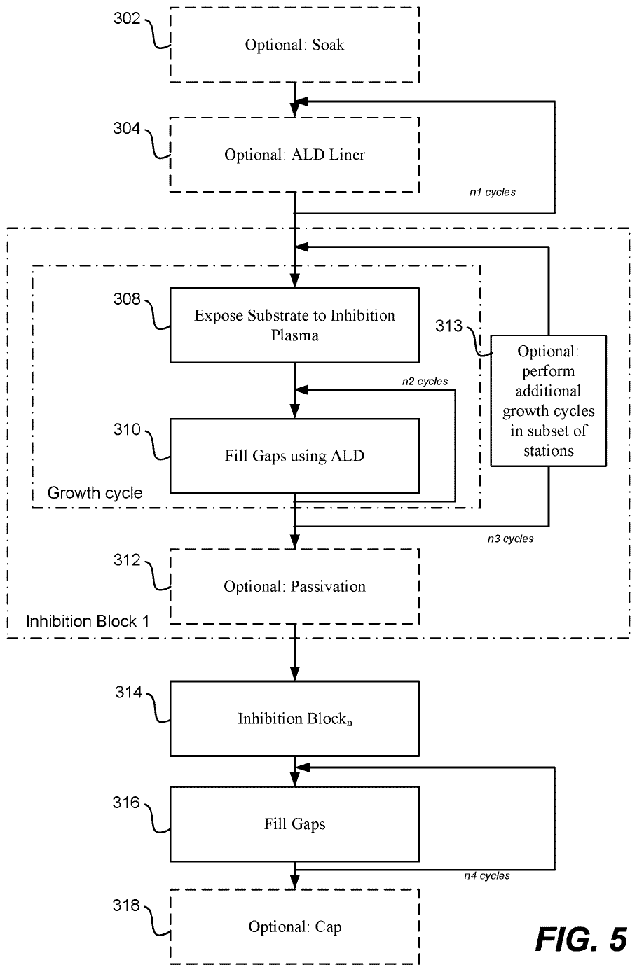

Another aspect of the present disclosure relates to the process shown in FIG. 1. In some embodiments, the process shown in FIG. 1 may be performed simultaneously in multiple stations of a process chamber or tool. As described further below in relation to FIGS. 5-8, a process chamber or tool may have multiple stations, where each station may be configured for receiving a substrate having structures with gaps to be filled. Gapfill processes described herein may be performed at each station simultaneously to fill gaps in each substrate, where each station may share or be connected to a central reactant delivery system or radio frequency (RF) power supply.

In some embodiments, gapfill may proceed at different rates between stations on a single tool or between stations across multiple tools. This difference in film growth rate between stations may be caused by various imbalances. For example, the fluid dynamics of reactant flow to each station or an RF generator at each station may perform differently, causing variations in processing between stations. Inhibition plasma processes as described herein may be particularly sensitive to such variations. In some embodiments, an NF₃ inhibition plasma treatment may be performed for as little as 0.1 seconds, such that a variation in plasma or flow characteristics between stations may affect the inhibition plasma, causing a commensurate change in growth rate from under-or over-inhibition. Unlike other ALD processes that may rely on saturation, a substrate may be exposed to an inhibition plasma for a sufficiently short duration to preferentially inhibit the upper portion of a gap in order to facilitate bottom-up fill. Thus, variations between stations, such as hardware variations, may cause some stations to fill at a slower rate than other stations, which is undesirable.

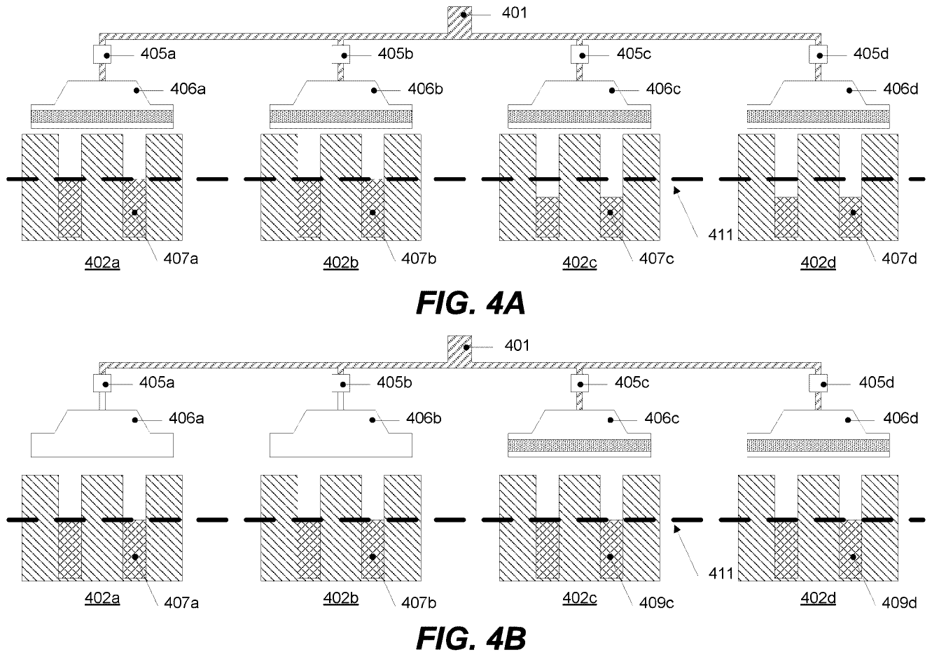

FIGS. 4A and 4B present illustrations of a 4-station process chamber (also referred to as a 4-station tool) according to various embodiments herein. In FIG. 4A, four stations 402a-d are presented, each having a corresponding showerhead 406a-d and showerhead inlet valve 405a-d. Each showerhead may be fluidically connected to a reactant delivery system 401. In some embodiments, each showerhead may comprise an RF generator that may be provided RF power in order to generate a plasma (the hatch pattern indicating the flow of RF power to a showerhead). In FIG. 4A, a gapfill process has been performed in each of stations 402a-d simultaneously. In stations 402a-b, dielectric material 407a-b have been deposited up to a target fill depth 411, while stations 402c-dare filled with dielectric material 407c-d that are lower than target fill depth 411. This difference in fill may be consistent between stations 402a-b and stations 402c-d, i.e., stations 402c-d consistently underfill across repeated operations on different substrates, indicating the variability in fill is not related to any wafer to wafer variability.

FIG. 4B illustrates a method of correcting this difference in fill by performing additional deposition in stations 402c-d but not in stations 402a-b. In station 402c-d, RF power may still be provided to generate a plasma (as illustrated by the dot pattern on showerheads 406c-d) while RF power is not provided to stations 402a-b. Similarly, reactant flow may be maintained to stations 402c-d but reactants do not flow to stations 402a-b (as illustrated by the lack of hatch pattern below showerhead inlet valves 405a-b). Showerhead inlet valves 405a-b may be closed to inhibit the flow of gas to stations 402a-b. As the reactant flow and plasma power are provided to stations 402c-d but not stations 402a-b, additional dielectric material will deposit on substrates in stations 402c-d, resulting in deposition of dielectric material 409c-d that are deposited up to target fill depth 411, matching the depth of fill in stations 402a-b and dielectric material 407a-b. In some embodiments, additional growth cycles are performed in stations 402c-d but not in stations 402a-b. For example, in FIG. 4B 50 growth cycles may be performed in stations 402a-b and 60 growth cycles may be performed in stations 402c-d, where the same total depth of dielectric fill is present in substrates of all stations despite the difference in the total number of growth cycles. During the 10 additional growth cycles performed in stations 402c-d deposition does not occur in stations 402a-b.

In some embodiments, both RF power and reactant flow may not be provided to stations 402a-b. In other embodiments, only RF power or only reactant flow may be stopped to some stations. In some embodiments, a deposition process is a plasma enhanced process such that in the absence of a plasma, reactants will not deposit or meaningfully interact with a substrate in the chamber. Thus, even if reactants are flowing, the lack of a plasma results in no deposition, inhibition or etch process. In some embodiments, not providing RF power to a station may be preferable to stopping reactant flow as stopping reactant flow to one or more stations may affect the flow of reactants to the other stations, which is undesirable.

Alternatively, in some embodiments, reactant flow may be stopped to one or more stations. This may be performed in embodiments where deposition may occur in the absence of a plasma, e.g., a thermal deposition process. In some embodiments, the station may be unable to sufficiently cool below a thermal deposition temperature without an expensive or time-consuming process. In the absence of reactants, deposition from such reactants will not occur.

In embodiments where RF power and/or reactant flow is stopped to one or more stations, RF power and/or reactant flow may be appropriately adjusted to account for the remaining stations where a deposition process may still be performed. For example, in some embodiments an RF power may be about 7000 W for a quad-station chamber, such as shown in FIG. 4A, with each station receiving about 1250 W. In FIG. 4B, the RF power may be adjusted to 2700 W to account for only two stations being provided RF power, where each station is still receiving about 1250 W. Similar alterations may be performed for reactant flow to maintain a similar per-station flow rate when depositing in two stations as when depositing in four stations.

FIG. 5 shows an example of a process sequence that may be used in accordance with the disclosed embodiments. FIG. 5 may disclose operations having the same reference numbers as disclosed above in relation to FIG. 3. Where the same reference numbers are used, the same or similar operations may be performed.

The process sequence in FIG. 5 includes treating a substrate with an inhibition plasma. Other operations (e.g., soak) may be omitted in certain embodiments and operations may be added in certain embodiments. In the example process sequence of FIG. 5, one or more wafers undergo gap fill. The process may begin with a soak after being provided to a deposition chamber. (302). This can be useful, for example, to remove particles or other pretreatment. Then, n1 cycles of ALD deposition of a liner are performed. (304). Further details of a liner ALD are discussed below.

After the optional liner is deposited, n inhibition blocks are performed, with the operations of the first inhibition block (n=1) shown. The first operation is the inhibition plasma, which is a surface treatment. (308) As discussed above, the plasma may include halogen species including anion and radical species such as F⁻, Cl⁻, I⁻, Br⁻, fluorine radicals, etc. Other inhibition plasmas may be used. In some embodiments, the inhibition plasma is generated from non-halogen containing species, including nitrogen-containing, non-halogen-containing species. For example, plasmas generated from molecular nitrogen (N₂), molecular hydrogen (H₂), ammonia (NH₃), amines, diols, diamines, aminoalcohols, thiols, alkyl halides, halides, HF, fluorine-containing species, chlorine-containing species, iodine-containing species, or combinations thereof may be used as inhibition plasmas.

When the inhibition plasma interacts with material in the feature, the material at the bottom of the feature receives less plasma treatment than material located closer to a top portion of the feature or in field because of geometrical shadowing effects. As a result, deposition at the top of the feature is selectively inhibited and deposition in lower portions of the feature proceeds with less inhibition or without being inhibited. In FIG. 5, the next operation in the inhibition block is n2 cycles of ALD fill. (310). The dielectric material is deposited selectively at the bottom of the feature. In some embodiments, n2 cycles of ALD fill may comprise at least one ALD cycle, at least about 10 ALD cycles, or between 1 and about 15 ALD cycles. The inhibition plasma and the n2 cycles of ALD fill together make a growth cycle. This can be repeated n3 times to continue filling the feature with intermittent inhibition operations when the inhibition effect diminishes.

In some embodiments, additional growth cycles may be performed on a subset of stations in a tool. (313). As described above, one or more stations in a tool may have a lower deposition rate such that features of substrates in that station are underfilled relative to other stations. Such substrates may have gaps that have a lower depth of fill of dielectric material than a substrate in a different station. Additional growth cycles may be performed in such underfilling stations. This may be accomplished by inhibiting RF power or reactant flow to other stations, such that during a subsequent growth cycle only a subset of stations will be filled with additional dielectric material. The additional growth cycles do not result in additional dielectric material deposition in stations that are not included in the subset of stations.

In some embodiments, additional n2 cycles of ALD fill are performed in a subset of stations. For example, during 310 n2 cycles of ALD fill may be performed in all stations, and an additional number of ALD cycles may be performed in a subset of stations.

In some embodiments, additional growth cycles may be performed for a subset of stations during each inhibition block. As noted above, each inhibition block may be characterized by an IED, which is a depth above which deposition is inhibited. If a gap is not sufficiently filled before the end of an inhibition block, during a subsequent inhibition block a void may form from a pinch-off effect. This may occur as the subsequent inhibition block will have a higher IED, such that deposition may occur higher in the gap. As the deposition will proceed from the sidewalls towards the center of the feature, reactants may be unable to diffuse to the bottom of the feature to completely fill with dielectric material due to film growth at a higher depth within the feature.

To avoid such pinch-off, in some embodiments additional ALD cycles or growth cycles may be performed in each inhibition block in a subset of stations. In some embodiments, each station may have substantially the same depth of fill of substrates between inhibition blocks. Thus, in some embodiments, additional n2 cycles, e.g., additional ALD cycles, may be performed in a subset of stations. In some embodiments, additional n3 cycles, e.g., additional inhibition plasma treatment and ALD cycles, may be performed in a subset of stations.

In various embodiments the subset of stations may be one, two, or three stations of a four-station tool. A tool may also have greater or fewer than four stations; in some embodiments, a tool has at least two stations, where additional growth cycles are only performed in one station. Additional growth cycles may be performed until the depth of fill in the subset of stations is substantially similar to the depth of fill in the stations that are not part of the subset of stations.

In the example of FIG. 5, the inhibition block ends with a passivation operation. (312). In some embodiments, a passivation operation may not be performed in every inhibition block. Passivation is a surface treatment that removes residual inhibitor and can also densify the deposited film. In some embodiments, a hydrogen and/or oxygen plasma is used.

One or more additional inhibition blocks, including growth cycle and passivation, may be performed for a total of n inhibition blocks. (314). The number of inhibition blocks depends on how much material is used to fill the feature. Inhibition plasma, ALD, and passivation conditions may be changed from inhibition block to inhibition block to fill the feature. For example, an inhibition plasma duration may be 20 seconds until the bottom quarter of the feature is filled (inhibition block 1), then changed to 5 seconds for the middle 50% of the structure (inhibition block 2), etc. Each inhibition block may have a different IED, where process parameters for an inhibition plasma treatment for an inhibition block are changed to target a different IED. Each inhibition block may fill a portion of the feature below an IED of that inhibition block.

In some embodiments additional inhibition blocks may be performed in a subset of stations. Similar to operation 311, above, an additional inhibition block, including inhibition plasma, ALD gapfill, and passivation may be performed in a subset of stations. The additional inhibition block is not performed in stations that are not part of the subset of stations, such that the additional inhibition block is only performed in the subset of stations.

When the feature is nearly filled, inhibition may no longer be necessary, and the fill can be completed with n4 cycles of ALD fill. (316). In some embodiments, an optional cap or overburden layer of dielectric may then be deposited. (318). Plasma enhanced chemical vapor deposition (PECVD) may be used at this stage for a fast deposition.

ALD is a technique that sequentially deposits thin layers of material. ALD processes use surface-mediated deposition reactions to deposit films on a layer-by-layer basis in cycles. The concept of an ALD “cycle” is relevant to the discussion of various embodiments herein. Generally, a cycle is the minimum set of operations used to perform a surface deposition reaction one time. The result of one cycle is the production of at least a partial silicon-containing film layer on a substrate surface. Typically, an ALD cycle includes operations to deliver and adsorb at least one reactant to the substrate surface, and then react the adsorbed reactant with one or more reactants to form the partial layer of film. The cycle may include certain ancillary operations such as sweeping one of the reactants or byproducts and/or treating the partial film as deposited. Generally, a cycle contains one instance of a unique sequence of operations.

As an example, an ALD cycle may include the following operations: (i) delivery/adsorption of a precursor, (ii) purging of the precursor from the chamber, (iii) delivery of a second reactant and optional plasma ignition, and (iv) purging of byproducts from the chamber. The reaction between the second reactant and the adsorbed precursor to form a film on the surface of a substrate affects the film composition and properties, such as nonuniformity, stress, wet etch rate, dry etch rate, electrical properties (e.g., breakdown voltage and leakage current), etc.

In one example of an ALD process, a substrate surface that includes a population of surface-active sites is exposed to a gas phase distribution of a first precursor, such as a silicon-containing precursor, in a dose provided to a chamber housing the substrate. Molecules of this first precursor are adsorbed onto the substrate surface, including chemisorbed species and/or physisorbed molecules of the first precursor. When a compound is adsorbed onto the substrate surface as described herein, the adsorbed layer may include the compound as well as derivatives of the compound. For example, an adsorbed layer of a silicon-containing precursor may include the silicon-containing precursor as well as derivatives of the silicon-containing precursor. After a first precursor dose, the chamber is then evacuated to remove most or all of first precursor remaining in gas phase so that mostly or only the adsorbed species remain. In some implementations, the chamber may not be fully evacuated. For example, the reactor may be evacuated such that the partial pressure of the first precursor in gas phase is sufficiently low to mitigate a reaction. A second reactant, such as an oxygen-containing gas or nitrogen-containing gas, is introduced to the chamber so that some of these molecules react with the first precursor adsorbed on the surface. In some processes, the second reactant reacts immediately with the adsorbed first precursor. In other embodiments, the second reactant reacts only if a source of activation such as plasma is applied temporally. The chamber may then be evacuated again to remove unbound second reactant molecules. As described above, in some embodiments the chamber may not be completely evacuated. Additional ALD cycles may be used to build film thickness.

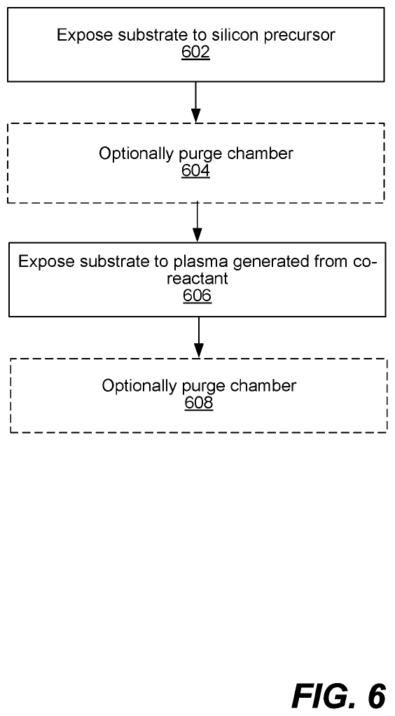

FIG. 6 presents a process flow diagram for a single plasma enhanced ALD cycle that may be implemented as part of operations 304, 310, and/or 316 shown in FIG. 3. In an operation 602, the substrate is exposed to a silicon-containing precursor, to adsorb the precursor onto the surface of the feature. This operation may be self-limiting. In some embodiments, the precursor adsorbs to less than all the active sites on the surface of the feature. In an operation 604, the process chamber is optionally purged to remove any unadsorbed silicon-containing precursors. In an operation 606, the substrate is exposed to a plasma generated from a co-reactant. Examples include O₂ and/or N₂O to form a silicon oxide layer or silicon oxynitride layer, N₂ or NH₃ to form a silicon nitride layer, methane (CH₄) to generate a silicon carbide layer etc. In operation 608, the process chamber is optionally purged to remove byproducts from the reaction between the silicon-containing precursor and the oxidant. Operations 602 through 608 repeated for a number of cycles to deposit the silicon-containing layer to a desired thickness in the feature.

It should be noted that the processes described herein are not limited to a particular reaction mechanism. Thus, the processes described with respect to FIGS. 3 and 4 include all deposition processes that use sequential exposures to silicon-containing reactants and conversion plasmas, including those that are not strictly self-limiting. The process includes sequences in which one or more gases used to generate a plasma is continuously flowed throughout the process with intermittent plasma ignitions.

In some embodiments, an inhibition plasma treatment may be performed at a pressure of more than about 1 Torr, at least about 10 Torr, at least about 15 Torr, at least about 20 Torr, between about 10 Torr and about 30 Torr, or between about 15 Torr and 30 Torr.

The duration of an inhibition plasma treatment may be between about 0.3 seconds and about 60 seconds, between about 0.3 seconds and about 30 seconds, at least about 0.3 seconds, at least about 1 second, at least about 5 seconds. at least about 10 seconds, at least about 20 seconds, or at least about 30 seconds. Inhibition plasma treatment using a halogen-containing species may generally be for a shorter duration than a non-halogen-containing species, as the halogen-containing species may more effectively passivate the surface compared to non-halogen-containing species.

Inhibition plasma treatment may be used for various aspect ratios and structure depths. In some embodiments, inhibition plasma treatment may be used for low aspect ratio structures. A low aspect ratio structure may have an aspect ratio between about 3:1 and about 7:1, less than about 10:1, between about 3:1 and about 10:1, between about 3:1 and about 15:1, or less than about 15:1. A low aspect ratio structure may have a depth of at least about 100 nm, at least about 1 μm, at least about 2 μm, or at least about 3 μm.

In some embodiments, IED may be characterized by a percentage, e.g., 30% IED refers to an inhibition effective depth of 30% of the total depth of a feature. Thus, if a feature has a depth of 1 μm, a 30% IED means deposition would be inhibited along the sidewall surface of the feature that is within 300 nm from the top of the feature, with the remaining depth not being inhibited. In some embodiments, the IED of an inhibition plasma treatment according to embodiments described herein may be about 20%, about 30%, about 40%, about 50%, about 60%, or about 70%.

In some embodiments, a structure may have reentrancy features that vary. In some embodiments, the critical dimension within a gap at any particular depth may vary by at least about 5%, at least about 10%, at least about 15%, at least about 20%, or between about 10% and about 20%. In some embodiments the size of a reentrancy feature may vary by at least about 5%, at least about 10%, at least about 15%, at least about 20%, or between about 10% and about 20%, wherein size may be based on a difference between the critical dimension at the narrowest and the critical dimension at the widest part of the reentrancy feature. In some embodiments, the depth of a reentrancy feature may vary by at least about 5%, at least about 10%, at least about 15%, at least about 20%, or between about 10% and about 20%.

In some embodiments the ratio of inhibition species to inert gas may be about 1:5, about 1:10, between about 1:10 and about 1:20, between about 1:100 and about 1:700, or between about 1:5 and about 1:7000. Generally, increasing the proportion of the gas flow that is the inhibiting species, such as NF₃, increases the inhibition effect of exposing the substrate to an inhibition plasma. Similarly, decreasing the proportion of the gas flow that is inhibiting species, either by modifying flow of the inhibition species or inert gases, will decrease an inhibition effect. In some embodiments, the flow of non-halogen-containing species, such as N₂, may be between about 10 slm and about 100 slm. In some embodiments, an inert gas may be co-flowed with the species used for inhibition. Inert gases may include helium, argon, xenon, or other gases that are non-reactive with the other species in the gas or surfaces of the substrate. The flow of inert gases, when used, may be between about 3.5 and about 15 slm or between about 10 slm and about 40 slm. In some embodiments, oxygen-or hydrogen-containing species may be co-flowed with the species used for inhibition. If the species used for inhibition includes a nitrogen atom, the nitrogen atom may react with silicon-containing precursors or the silicon film to form silicon nitride. Adding oxygen-or hydrogen-containing species may inhibit conversion of silicon oxide or silicon to silicon nitride, respectively. In some embodiments, co-flows of oxygen-or hydrogen-containing species may be at least about 100 sccm, or between about 0 and about 5 slm.

In various embodiments, the plasma is an in-situ plasma, such that the plasma is formed directly above the substrate surface in the station. Example power per substrate areas for an in-situ plasma are between about 0.2122 W/cm² and about 2.122 W/cm² in some embodiments. For example, the power may range from about 1000 W to about 8000 W for a chamber processing four 300 mm wafers. In some embodiments, the power may be between about 2700 W and about 8000 W for four 300 mm wafers. Plasmas for ALD processes may be generated by applying a radio frequency (RF) field to a gas using two capacitively coupled plates. Ionization of the gas between plates by the RF field ignites the plasma, creating free electrons in the plasma discharge region. These electrons are accelerated by the RF field and may collide with gas phase reactant molecules. Collision of these electrons with reactant molecules may form radical species that participate in the deposition process. It will be appreciated that the RF field may be coupled via any suitable electrodes. Non-limiting examples of electrodes include process gas distribution showerheads and substrate support pedestals. It will be appreciated that plasmas for ALD processes may be formed by one or more suitable methods other than capacitive coupling of an RF field to a gas. In some embodiments, the plasma is a remote plasma, such that second reactant is ignited in a remote plasma generator upstream of the station, then delivered to the station where the substrate is housed.

For depositing silicon-containing films, one or more silicon-containing precursors may be used. In some examples, silicon-containing precursors can include silanes (e.g., SiH₄), polysilanes (H₃Si—(SiH₂)ₙ-SiH₃) where n≥1, organosilanes, halogenated silanes, aminosilanes, alkoxysilanes, and the like. Organosilanes such as methylsilane, ethylsilane, isopropylsilane, t-butylsilane, dimethylsilane, diethylsilane, di-t-butylsilane, allylsilane, sec-butylsilane, thexylsilane, isoamylsilane, t-butyldisilane, di-t-butyldisilane, and the like.

A halosilane includes at least one halogen group and may or may not include hydrogens and/or carbon groups. Examples of halosilanes are iodosilanes, bromosilanes, chlorosilanes, and fluorosilanes. Specific chlorosilanes are tetrachlorosilane, trichlorosilane, dichlorosilane, monochlorosilane, chloroallylsilane, chloromethylsilane, dichloromethylsilane, chlorodimethylsilane, chloroethylsilane, t-butylchlorosilane, di-t-butylchlorosilane, chloroisopropylsilane, chloro-sec-butylsilane, t-butyldimethylchlorosilane, thexyldimethylchlorosilane, and the like.

An aminosilane includes at least one nitrogen atom bonded to a silicon atom, but may also contain hydrogens, oxygens, halogens, and carbons. Examples of aminosilanes are mono-, di-, tri- and tetra-aminosilane (H₃Si(NH₂), H₂Si(NH₂)₂, HSi(NH₂)₃ and Si(NH₂)₄, respectively), as well as substituted mono-, di-, tri- and tetra-aminosilanes, for example, t-butylaminosilane, methylaminosilane, tert-butylsilanamine, bis(tert-butylamino)silane (SiH₂(NHC(CH₃)₃)₂ (BTBAS), tert-butyl silylcarbamate, SiH(CH₃)-(N(CH₃)₂)₂, SiHC₁-(N(CH₃)₂)₂, (Si(CH₃)₂NH)₃, di-isopropylaminosilane (DIPAS), di-sec-butylaminosilane (DSBAS), SiH₂[N(CH₂CH₃)₂]₂ (BDEAS) and the like. A further example of an aminosilane is trisilylamine (N(SiH₃)). In some embodiments, an aminosilane that has two or more amine groups attached to the central Si atom may be used. These may result in less damage than aminosilanes having only a single amine group attached.

Further examples of silicon-containing precursors include trimethylsilane (3MS); ethylsilane; butasilanes; pentasilanes; octasilanes; heptasilane; hexasilane; cyclobutasilane; cycloheptasilane; cyclohexasilane; cyclooctasilane; cyclopentasilane; 1,4-dioxa-2,3,5,6-tetrasilacyclohexane; diethoxymethylsilane (DEMS); diethoxysilane (DES); dimethoxymethylsilane; dimethoxysilane (DMOS); methyl-diethoxysilane (MDES); methyl-dimethoxysilane (MDMS); octamethoxydodecasiloxane (OMODDS); tert-butoxydisilane; tetramethylcyclotetrasiloxane (TMCTS); tetraoxymethylcyclotetrasiloxane (TOMCTS); triethoxysilane (TES); triethoxysiloxane (TRIES); and trimethoxysilane (TMS or TriMOS).

In some implementations silicon-containing precursors may include siloxanes or amino-group-containing siloxanes. In some embodiments, siloxanes used herein may have a formula of X(R¹)ₐSi—O—Si(R²)_{b}Y, where a and b are integers from 0 to 2, and X and Y independently can be H or NR³R⁴, where each of R1, R2, R3 and R4 is hydrogen, unbranched alkyl, branched alkyl, saturated heterocyclic, unsaturated heterocyclic groups, or combinations thereof. In some embodiments, when at least one X or Y is NR³R⁴, R3 and R4, taken together with the atom to which each are attached, form a saturated heterocyclic compound. In some embodiments, the silicon-containing precursors are pentamethylated amino group containing siloxanes or dimethylated amino group containing siloxanes. Examples of amino group containing siloxanes include: 1-diethylamino 1,1,3,3,3,-pentamethyl disiloxane, 1-diisopropylamino-1,1,3,3,3,-pentamethyl disiloxane, 1 dipropylamino-1,1,3,3,3,-pentamethyl disiloxane, 1-di-n-butylamino-1,1,3,3,3,-pentamethyl 1 disiloxane, 1-di-sec-butylamino-1,1,3,3,3,-pentamethyl disiloxane, 1-N-methylethylamino 1,1,3,3,3,-pentamethyl disiloxane, 1-N-methylpropylamino-1,1,3,3,3,-pentamethyl disiloxane, 1 N-methylbutylamino-1,1,3,3,3,-pentamethyl disiloxane, 1-t-butylamino-1,1,3,3,3,-pentamethyl disiloxane, 1-piperidino-1,1,3,3,3,-pentamethyl disiloxane, 1-dimethylamino-1,1-dimethyl disiloxane, 1-diethylamino-1,1-dimethyl disiloxane, 1-diisopropylamino-1,1-dimethyl disiloxane, 1-dipropylamino-1,1-dimethyl disiloxane, 1-di-n-butylamino-1,1-dimethyl disiloxane, 1-di-sec butylamino-1,1-dimethyl disiloxane, 1-N-methylethylamino-1,1-dimethyl disiloxane, 1-N methylpropylamino-1,1-dimethyl disiloxan, e 1-N-methylbutylamino-1,1-dimethyl disiloxane, 1 piperidino-1,1-dimethyl disiloxane, 1-t-butylamino-1,1-dimethyl disiloxane, 1-dimethylamino-disiloxane, 1-diethylamino-disiloxane, 1-diisopropylamino-disiloxane, 1-dipropylamino-disiloxane, 1-di-n-butylamino-disiloxane, 1-di-sec-butylamino-disiloxane, 1-N methylethylamino-disiloxane, 1-N-methylpropylamino-disiloxane, 1-N-methylbutylamino-disiloxane, 1-piperidino-disiloxane, 1-t-butylamino disiloxane, and 1-dimethylamino-1,1,5,5,5,-pentamethyl disiloxane.

Where a deposited film includes oxygen, an oxygen-containing reactant may be used. Examples of oxygen-containing reactants include, but are not limited to, oxygen (O₂), ozone (O₃), nitrous oxide (N₂O), nitric oxide (NO), nitrogen dioxide (NO₂), dinitrogen trioxide (N₂O₃), dinitrogen tetroxide (N₂O4), dinitrogen pentoxide (N₂O5), carbon monoxide (CO), carbon dioxide (CO₂), sulfur oxide (SO), sulfur dioxide (SO₂), oxygen-containing hydrocarbons (CₓH_{y}O_{z}), water (H₂O), formaldehyde (CH₂O), carbonyl sulfide (COS), mixtures thereof, etc.

Where a deposited film includes nitrogen, a nitrogen-containing reactant may be used. A nitrogen-containing reactant contains at least one nitrogen, for example, nitrogen (N₂), ammonia (NH₃), hydrazine (N₂H₄), amines (e.g., amines bearing carbon) such as methylamine (CH₅N), dimethylamine ((CH₃)₂NH), ethylamine (C₂H₅NH₂), isopropylamine (C₃H₉N), t-butylamine (C₄H₁₁N), di-t-butylamine (C₈H₁₉N), cyclopropylamine (C₃H₅NH₂), sec-butylamine (C₄H₁N), cyclobutylamine (C₄H₇NH₂), isoamylamine (C₅H₁₃N), 2-methylbutan-2-amine (C₅H₁₃N), trimethylamine (C₃H₉N), diisopropylamine (C₆H₁₅N), diethylisopropylamine (C₇H₁₇N), di-t-butylhydrazine (C₈H₂₀N₂), as well as aromatic containing amines such as anilines, pyridines, and benzylamines. Amines may be primary, secondary, tertiary or quaternary (for example, tetraalkylammonium compounds). A nitrogen-containing reactant can contain heteroatoms other than nitrogen, for example, hydroxylamine, t-butyloxycarbonyl amine and N-t-butyl hydroxylamine are nitrogen-containing reactants. Other examples include NₓO_{y} compounds such as nitrous oxide (N2O), nitric oxide (NO), nitrogen dioxide (NO₂), dinitrogen trioxide (N₂O₃), dinitrogen tetroxide (N₂O₄) and/or dinitrogen pentoxide (N₂O₅).

### Apparatus

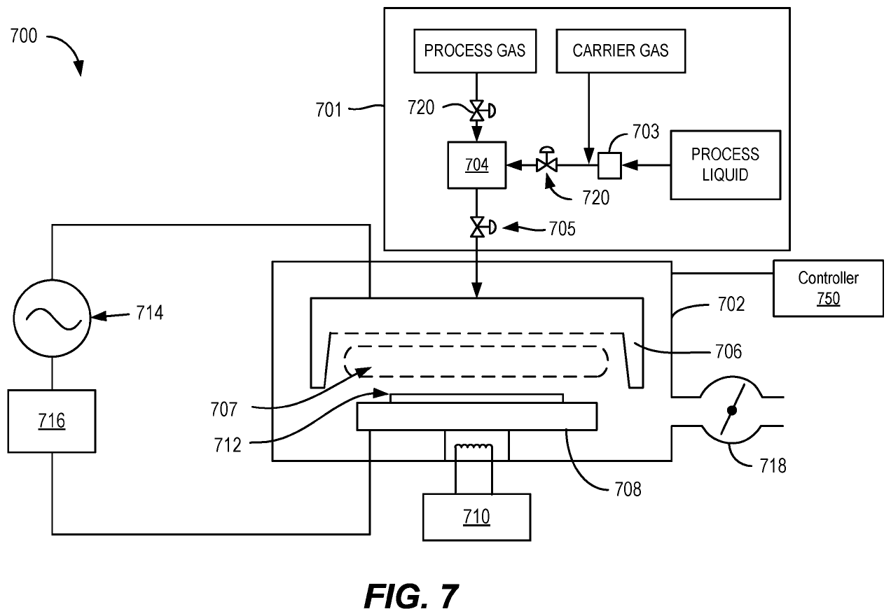

FIG. 7 schematically shows an embodiment of a process station 700 that may be used to deposit material using atomic layer deposition (ALD) and/or chemical vapor deposition (CVD), either of which may be plasma enhanced. For simplicity, the process station 700 is depicted as a standalone process station having a process chamber body 702 for maintaining a low-pressure environment. However, it will be appreciated that a plurality of process stations 700 may be included in a common process tool environment. Further, it will be appreciated that, in some embodiments, one or more hardware parameters of process station 700, including those discussed in detail below, may be adjusted programmatically by one or more computer controllers 750.

Process station 700 fluidly communicates with reactant delivery system 701 for delivering process gases to a distribution showerhead 706. Reactant delivery system 701 includes a mixing vessel 704 for blending and/or conditioning process gases for delivery to showerhead 706. One or more mixing vessel inlet valves 720 may control introduction of process gases to mixing vessel 704. Similarly, a showerhead inlet valve 705 may control introduction of process gasses to the showerhead 706. In some embodiments, an inhibitor or other gas may be directly delivered to the chamber body 702. One or more mixing vessel inlet valves 720 may control introduction of process gases to mixing vessel 704. These valves may be controlled depending on whether a process gas, inhibition gas, or carrier gas may be turned on during various operations. In some embodiments, an inhibition gas may be generated by using an inhibition liquid and vaporizing using a heated vaporizer.

As an example, the embodiment of FIG. 7 includes a vaporization point 703 for vaporizing liquid reactant to be supplied to mixing vessel 704. In some embodiments, vaporization point 703 may be a heated vaporizer. The reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve sweeping and/or evacuating the delivery piping to remove residual reactant. However, sweeping the delivery piping may increase process station cycle time, degrading process station throughput. Thus, in some embodiments, delivery piping downstream of vaporization point 703 may be heat traced. In some examples, mixing vessel 704 may also be heat traced. In one non-limiting example, piping downstream of vaporization point 703 has an increasing temperature profile extending from approximately 100° C. to approximately 150° C. at mixing vessel 704.

In some embodiments, reactant liquid may be vaporized at a liquid injector. For example, a liquid injector may inject pulses of a liquid reactant into a carrier gas stream upstream of the mixing vessel. In one scenario, a liquid injector may vaporize reactant by flashing the liquid from a higher pressure to a lower pressure. In another scenario, a liquid injector may atomize the liquid into dispersed microdroplets that are subsequently vaporized in a heated delivery pipe. It will be appreciated that smaller droplets may vaporize faster than larger droplets, reducing a delay between liquid injection and complete vaporization. Faster vaporization may reduce a length of piping downstream from vaporization point 703. In one scenario, a liquid injector may be mounted directly to mixing vessel 704. In another scenario, a liquid injector may be mounted directly to showerhead 706.

In some embodiments, a liquid flow controller (LFC) upstream of vaporization point 703 may be provided for controlling a mass flow of liquid for vaporization and delivery to process station 700. For example, the liquid flow controller may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, the LFC may be dynamically switched from a feedback control mode to a direct control mode by disabling a sense tube of the LFC and the PID controller.

Showerhead 706 distributes process gases toward substrate 712. In the embodiment shown in FIG. 7, substrate 712 is located beneath showerhead 706, and is shown resting on a pedestal 708. It will be appreciated that showerhead 706 may have any suitable shape, and may have any suitable number and arrangement of ports for distributing processes gases to substrate 712.

In some embodiments, a microvolume 707 is located beneath showerhead 706. Performing an ALD and/or CVD process in a microvolume rather than in the entire volume of a process station may reduce reactant exposure and sweep times, may reduce times for altering process conditions (e.g., pressure, temperature, etc.), may limit an exposure of process station robotics to process gases, etc. Example microvolume sizes include, but are not limited to, volumes between 0.1 liter and 2 liters. This microvolume also impacts productivity throughput. While deposition rate per cycle drops, the cycle time also simultaneously reduces. In certain cases, the effect of the latter is dramatic enough to improve overall throughput of the module for a given target thickness of film.

In some embodiments, pedestal 708 may be raised or lowered to expose substrate 712 to microvolume 707 and/or to vary a volume of microvolume 707. For example, in a substrate transfer phase, pedestal 708 may be lowered to allow substrate 712 to be loaded onto pedestal 708. During a deposition process phase, pedestal 708 may be raised to position substrate 712 within microvolume 707. In some embodiments, microvolume 707 may completely enclose substrate 712 as well as a portion of pedestal 708 to create a region of high flow impedance during a deposition process.

Optionally, pedestal 708 may be lowered and/or raised during portions the deposition process to modulate process pressure, reactant concentration, etc., within microvolume 707. In one scenario where process chamber body 702 remains at a base pressure during the deposition process, lowering pedestal 708 may allow microvolume 707 to be evacuated. Example ratios of microvolume to process chamber volume include, but are not limited to, volume ratios between 1:700 and 1:10. It will be appreciated that, in some embodiments, pedestal height may be adjusted programmatically by a suitable computer controller.

In another scenario, adjusting a height of pedestal 708 may allow a plasma density to be varied during plasma activation and/or treatment cycles included in the deposition process. At the conclusion of the deposition process phase, pedestal 708 may be lowered during another substrate transfer phase to allow removal of substrate 712 from pedestal 708.

While the example microvolume variations described herein refer to a height-adjustable pedestal, it will be appreciated that, in some embodiments, a position of showerhead 706 may be adjusted relative to pedestal 708 to vary a volume of microvolume 707. Further, it will be appreciated that a vertical position of pedestal 708 and/or showerhead 706 may be varied by any suitable mechanism within the scope of the present disclosure. In some embodiments, pedestal 708 may include a rotational axis for rotating an orientation of substrate 712. It will be appreciated that, in some embodiments, one or more of these example adjustments may be performed programmatically by one or more suitable computer controllers.

Returning to the embodiment shown in FIG. 7, showerhead 706 and pedestal 708 electrically communicate with RF power supply 714 and matching network 716 for powering a plasma. In some embodiments, the plasma energy may be controlled by controlling one or more of a process station pressure, a gas concentration, an RF source power, an RF source frequency, and a plasma power pulse timing. For example, RF power supply 714 and matching network 716 may be operated at any suitable power to form a plasma having a desired composition of radical species. Examples of suitable powers are included above. Likewise, RF power supply 714 may provide RF power of any suitable frequency. In some embodiments, RF power supply 714 may be configured to control high-and low-frequency RF power sources independently of one another. Example low-frequency RF frequencies may include, but are not limited to, frequencies between 50 kHz and 700 kHz. Example high-frequency RF frequencies may include, but are not limited to, frequencies between 1.8 MHz and 2.45 GHz. It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, the plasma may be controlled via input/output control (IOC) sequencing instructions. In one example, the instructions for setting plasma conditions for a plasma process phase may be included in a corresponding plasma activation recipe phase of a deposition process recipe. In some cases, process recipe phases may be sequentially arranged, so that all instructions for a deposition process phase are executed concurrently with that process phase. In some embodiments, instructions for setting one or more plasma parameters may be included in a recipe phase preceding a plasma process phase. For example, a first recipe phase may include instructions for setting a flow rate of an inert and/or a reactant gas, instructions for setting a plasma generator to a power set point, and time delay instructions for the first recipe phase. A second, subsequent recipe phase may include instructions for enabling the plasma generator and time delay instructions for the second recipe phase. A third recipe phase may include instructions for disabling the plasma generator and time delay instructions for the third recipe phase. It will be appreciated that these recipe phases may be further subdivided and/or iterated in any suitable way within the scope of the present disclosure.

In some deposition processes, plasma strikes last on the order of a few seconds or more in duration. In certain implementations, much shorter plasma strikes may be used. These may be on the order of 10 ms to 1 second, typically, about 20 to 80 ms, with 50 ms being a specific example. Such very short RF plasma strikes require extremely quick stabilization of the plasma. To accomplish this, the plasma generator may be configured such that the impedance match is set preset to a particular voltage, while the frequency is allowed to float. Conventionally, high-frequency plasmas are generated at an RF frequency at about 13.56 MHZ. In various embodiments disclosed herein, the frequency is allowed to float to a value that is different from this standard value. By permitting the frequency to float while fixing the impedance match to a predetermined voltage, the plasma can stabilize much more quickly, a result which may be important when using the very short plasma strikes associated with some types of deposition cycles.

In some embodiments, pedestal 708 may be temperature controlled via heater 710. Further, in some embodiments, pressure control for deposition process station 700 may be provided by butterfly valve 718. As shown in the embodiment of FIG. 7, butterfly valve 718 throttles a vacuum provided by a downstream vacuum pump (not shown). However, in some embodiments, pressure control of process station 700 may also be adjusted by varying a flow rate of one or more gases introduced to process station 700.

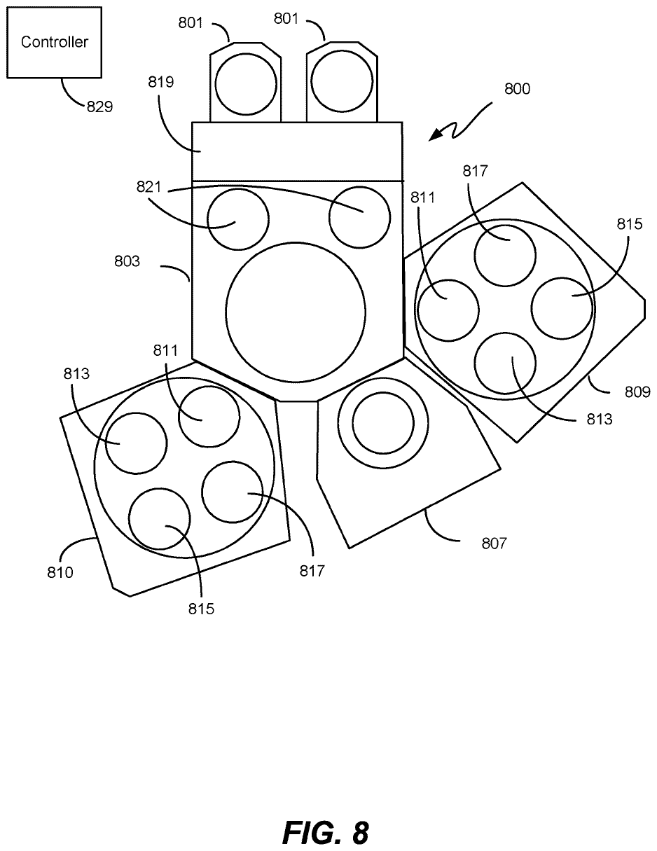

FIG. 8 is a block diagram of a processing system suitable for conducting thin film deposition processes in accordance with certain embodiments. The system 800 includes a transfer module 803. The transfer module 803 provides a clean, pressurized environment to minimize risk of contamination of substrates being processed as they are moved between various reactor modules. Mounted on the transfer module 803 are two multi-station reactors 809 and 810, each capable of performing atomic layer deposition (ALD) and/or chemical vapor deposition (CVD) according to certain embodiments. Reactors 809 and 810 may include multiple stations 811, 813, 815, and 817 that may sequentially or non-sequentially perform operations in accordance with disclosed embodiments. The stations may include a heated pedestal or substrate support, one or more gas inlets or showerhead or dispersion plate.

Also mounted on the transfer module 803 may be one or more single or multi-station modules 807 capable of performing plasma or chemical (non-plasma) pre-cleans, or any other processes described in relation to the disclosed methods. The module 807 may in some cases be used for various treatments to, for example, prepare a substrate for a deposition process. The module 807 may also be designed/configured to perform various other processes such as etching or polishing. The system 800 also includes one or more wafer source modules 801, where wafers are stored before and after processing. An atmospheric robot (not shown) in the atmospheric transfer chamber 819 may first remove wafers from the source modules 801 to loadlocks 821. A wafer transfer device (generally a robot arm unit) in the transfer module 803 moves the wafers from loadlocks 821 to and among the modules mounted on the transfer module 803.

In various embodiments, a system controller 829 is employed to control process conditions during deposition. The controller 829 will typically include one or more memory devices and one or more processors. A processor may include a CPU or computer, analog and/or digital input/output connections, stepper motor controller boards, etc.

The controller 829 may control all of the activities of the deposition apparatus. The system controller 829 executes system control software, including sets of instructions for controlling the timing, mixture of gases, chamber pressure, chamber temperature, wafer temperature, radio frequency (RF) power levels, wafer chuck or pedestal position, and other parameters of a particular process. Other computer programs stored on memory devices associated with the controller 829 may be employed in some embodiments.

Typically, there will be a user interface associated with the controller 829. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general purpose processor. System control software may be coded in any suitable computer readable programming language.

The computer program code for controlling the inhibition species flow, RF power, hydrogen flow, oxygen flow, and silicon-containing precursor flow, and other processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe, and may be entered utilizing the user interface. Signals for monitoring the process may be provided by analog and/or digital input connections of the system controller 829. The signals for controlling the process are output on the analog and digital output connections of the deposition apparatus 800.

The system software may be designed or configured in many different ways. For example, various chamber component subroutines or control objects may be written to control operation of the chamber components necessary to carry out the deposition processes (and other processes, in some cases) in accordance with the disclosed embodiments. Examples of programs or sections of programs for this purpose include substrate positioning code, process gas control code, pressure control code, and heater control code.

In some implementations, a controller, such as controller 750 or 829, is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 829, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

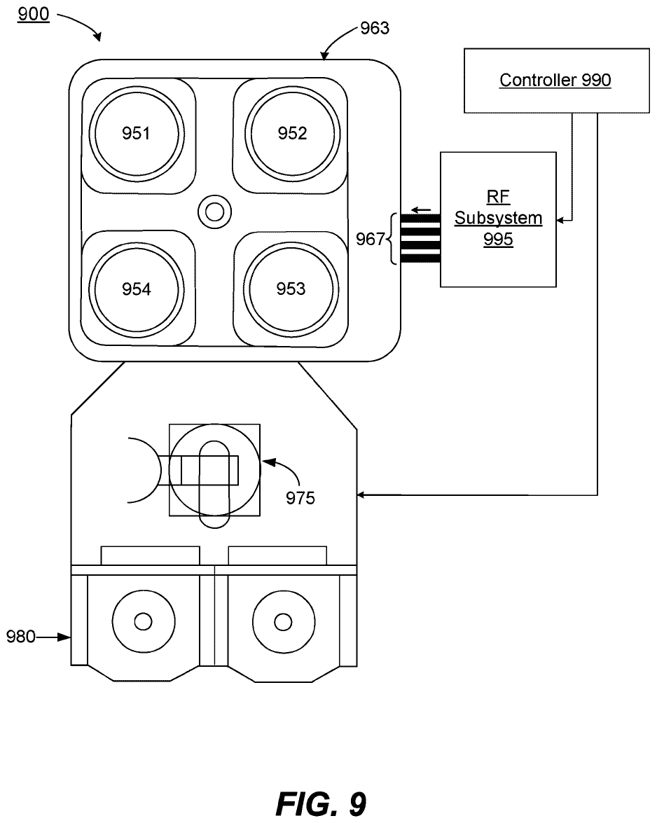

It may be appreciated that a plurality of process stations may be included in a multi-station processing tool environment, such as shown in FIG. 9, which depicts a schematic view of an embodiment of a multi-station processing tool. Processing apparatus 900 employs an integrated circuit fabrication chamber 963 that includes multiple fabrication process stations, each of which may be used to perform processing operations on a substrate held in a wafer holder, such as a pedestal, at a particular process station. In the embodiment of FIG. 9, the integrated circuit fabrication chamber 963 is shown having four process stations 951, 952, 953, and 954. Other similar multi-station processing apparatuses may have more or fewer process stations depending on the implementation and, for example, a desired level of parallel wafer processing, size/space constraints, cost constraints, etc. Also shown in FIG. 9 is substrate handler robot 975, which may operate under the control of system controller 990, configured to move substrates from a wafer cassette (not shown in FIG. 9) from loading port 980 and into integrated circuit fabrication chamber 963, and onto one of process stations 951, 952, 953, and 954.

FIG. 9 also depicts an embodiment of a system controller 990 employed to control process conditions and hardware states of processing apparatus 900. System controller 990 may include one or more memory devices, one or more mass storage devices, and one or more processors, as described herein.

RF subsystem 995 may generate and convey RF power to integrated circuit fabrication chamber 963 via radio frequency input ports 967. In particular embodiments, integrated circuit fabrication chamber 963 may comprise input ports in addition to radio frequency input ports 967 (additional input ports not shown in FIG. 9). Accordingly, integrated circuit fabrication chamber 963 may utilize 8 RF input ports. In particular embodiments, process stations 951-954 of integrated circuit fabrication chamber 963 may each utilize first and second input ports in which a first input port may convey a signal having a first frequency and in which a second input port may convey a signal having a second frequency. Use of dual frequencies may bring about enhanced plasma characteristics.

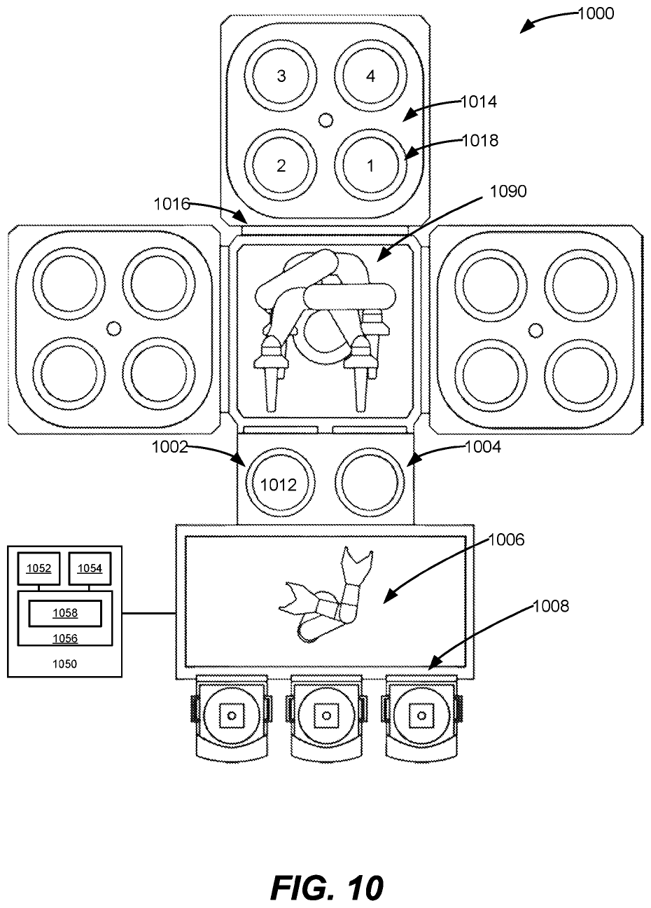

As described above, one or more process stations may be included in a multi-station processing tool. FIG. 10 shows a schematic view of an embodiment of a multi-station processing tool 1000 with an inbound load lock 1002 and an outbound load lock 1004, either or both of which may comprise a remote plasma source. A robot 1006, at atmospheric pressure, is configured to move substrates or wafers from a cassette loaded through a pod 1008 into inbound load lock 1002 via an atmospheric port. A substrate is placed by the robot 1006 on a pedestal 1012 in the inbound load lock 1002, the atmospheric port is closed, and the load lock is pumped down. Where the inbound load lock 1002 comprises a remote plasma source, the substrate may be exposed to a remote plasma treatment in the load lock prior to being introduced into a processing chamber 1014. Further, the substrate also may be heated in the inbound load lock 1002 as well, for example, to remove moisture and adsorbed gases. Next, a chamber transport port 1016 to processing chamber 1014 is opened, and another robot 1090 places the substrate into the reactor on a pedestal of a first station shown in the reactor for processing. While the embodiment depicted in FIG. 9 includes load locks, it will be appreciated that, in some embodiments, direct entry of a substrate into a process station may be provided. In various embodiments, the soak gas is introduced to the station when the substrate is placed by the robot 1006 on the pedestal 1012.

The depicted processing chamber 1014 comprises four process stations, numbered from 1 to 4 in the embodiment shown in FIG. 10. Each station has a heated pedestal (shown at 1018 for station 1), and gas line inlets. It will be appreciated that in some embodiments, each process station may have different or multiple purposes. For example, in some embodiments, a process station may be switchable between an inhibition plasma, passivation plasma, ALD and/or PEALD process mode. Additionally, or alternatively, in some embodiments, processing chamber 1014 may include one or more matched pairs of ALD and plasma-enhanced ALD process stations. While the depicted processing chamber 1014 includes four stations, it will be understood that a processing chamber according to the present disclosure may have any suitable number of stations. For example, in some embodiments, a processing chamber may have five or more stations, while in other embodiments a processing chamber may have three or fewer stations.

FIG. 10 depicts an embodiment of a wafer handling system 1090 for transferring substrates within processing chamber 1014. In some embodiments, wafer handling system 1090 may transfer substrates between various process stations and/or between a process station and a load lock. It will be appreciated that any suitable wafer handling system may be employed. Non-limiting examples include wafer carousels and wafer handling robots. FIG. 10 also depicts an embodiment of a system controller 1050 employed to control process conditions and hardware states of process tool 1000. System controller 1050 may include one or more memory devices 1056, one or more mass storage devices 1054, and one or more processors 1052. Processor 1052 may include a CPU or computer, analog and/or digital input/output connections, stepper motor controller boards, etc. In some embodiments, system controller 1050 includes machine-readable instructions for performing operations such as those described herein.

In some embodiments, system controller 1050 controls the activities of process tool 1000. System controller 1050 executes system control software 1058 stored in mass storage device 1054, loaded into memory device 1056, and executed on processor 1052. Alternatively, the control logic may be hard coded in the system controller 1050. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software 1058 may include instructions for controlling the timing, mixture of gases, amount of gas flow, chamber and/or station pressure, chamber and/or station temperature, substrate temperature, target power levels, RF power levels, substrate pedestal, chuck and/or susceptor position, and other parameters of a particular process performed by process tool 1000. System control software 1058 may be configured in any suitable way. For example, various process tool component subroutines or control objects may be written to control operation of the process tool components used to carry out various process tool processes. System control software 1058 may be coded in any suitable computer readable programming language.

### Conclusion

Although the foregoing embodiments have been described in some detail for purposes of clarity of understanding, it will be apparent that certain changes and modifications may be practiced within the scope of the appended claims. Embodiments disclosed herein may be practiced without some or all of these specific details. In other instances, well-known process operations have not been described in detail to not unnecessarily obscure the disclosed embodiments. Further, while the disclosed embodiments will be described in conjunction with specific embodiments, it will be understood that the specific embodiments are not intended to limit the disclosed embodiments. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method, comprising:
providing a substrate in a process chamber, the substrate having one or more structures, each structure comprising a gap; and
performing a first set of cycles of:
(a) exposing the substrate to an inhibition plasma to inhibit deposition on a first portion of each gap, and
(b) after (a), depositing a dielectric material in each gap, wherein, during a first subset and a second subset of the first set of cycles exposing the substrate to the inhibition plasma occurs for a first duration and during the second subset of the first set of cycles at least one non-duration based parameter of exposing the substrate to the inhibition plasma is modified.

2. The method of claim 1, wherein the non-duration based parameter is a flow rate of inhibition species, flow rate of a dilution gas, pressure, or a radio frequency (RF) power.

3. The method of claim 1, wherein the first subset of the first set of cycles inhibits deposition in the gaps to a greater depth of the gaps than the second subset of the first set of cycles.

4. The method of claim 1, wherein exposing the substrate to an inhibition plasma comprises flowing an inhibition species into the process chamber, and wherein a flow of inhibition species is lower during the second subset of the first set of cycles than the first subset of the first set of cycles.

5. The method of claim 4, wherein a difference in the flow of inhibition species between the first subset of the first set of cycles and the second subset of the first set of cycles is between about 1 sccm and about 5 sccm.

6. The method of claim 1, wherein exposing the substrate to an inhibition plasma comprises co-flowing an inhibition species with an inert gas into the process chamber, and wherein a ratio of inhibition species to inert gas is higher during the second subset of the first set of cycles than the first subset of the first set of cycles.

7. The method of claim 4, wherein the inhibition species comprises a nitrogen-containing species.

8. The method of claim 1, wherein exposing the substrate to an inhibition plasma comprises providing radio frequency (RF) energy to the process chamber, and wherein a RF is lower during the second subset of the first set of cycles than the first subset of the first set of cycles.

9. The method of claim 8, wherein a difference in RF power between the first subset of the first set of cycles and the second subset of the first set of cycles is between about 50 W and about 700 W.

10. The method of claim 8, wherein the RF power is between about 250 W and about 1250 W per substrate.

11. The method of claim 1, wherein each of the one or more structures has one or more reentrancy features.

12. The method of claim 11, wherein at least one of the reentrancy features has a variation in critical dimension of at least 10% within the substrate.

13. The method of claim 12, wherein the at least one non-duration based parameter is modified based on the variation in critical dimension of the at least one reentrancy feature of the one or more structures.

14. The method of claim 11, wherein at least one of the reentrancy features has a variation in depth of at least 10% between structures.

15. The method of claim 14, wherein the at least one non-duration based parameter is modified based on the variation in depth of the at least one reentrancy feature of the one or more structures.

16. The method of claim 1, wherein the dielectric material is an oxide material.

17. The method of claim 16, wherein the oxide material is silicon dioxide.

18. The method of claim 1, further comprising performing a second set of cycles of:
(a) exposing the substrate to an inhibition plasma to inhibit deposition on a second portion of the gaps, wherein, during a first subset and a second subset of the second set of cycles exposing the substrate to an inhibition plasma occurs for a second duration different than the first duration and during the second subset of the second set of cycles the at least one non-duration based parameter of the inhibition plasma is modified; and
(b) after (a), depositing a dielectric material in the gaps.

19. A system, comprising:
a process chamber, and
one or more memories and one or more processors, the one or more memories being configured with computer-executable instructions for controlling the one or more processors for:
providing a substrate in the process chamber, the substrate having one or more structures, each structure comprising a gap; and
performing a first set of cycles of:
(a) exposing the substrate to an inhibition plasma to inhibit deposition on a first portion of each gap, and
(b) after (a), depositing a dielectric material in each gap, wherein, during a first subset and a second subset of the first set of cycles exposing the substrate to the inhibition plasma occurs for a first duration and during the second subset of the first set of cycles at least one non-duration based parameter of exposing the substrate to the inhibition plasma is modified.

20. A system, comprising:
a process chamber comprising a plurality of stations;
one or more processors and one or more memories configured for:
receiving a plurality of substrates each having a structure with a gap in the plurality of stations, performing a first set of cycles in each of the stations of:
(a) exposing a substrate to an inhibition plasma to inhibit deposition on a first portion of the gaps, and
(b) after (a), depositing a dielectric material in the gaps, and
after performing the first set of cycles, performing a second set of cycles in each station of a first subset of the plurality of stations of:
(c) depositing dielectric material in only the gaps of substrates in stations of the first subset of the plurality of stations.

21. (canceled)
